(19) United States
(12) Patent Application Publication
(10) Pub. No.: US 2026/0074169 A1
(43) Pub. Date: Mar. 12, 2026

(54) Plasma Measurement Method and Plasma Measurement System

(71) Applicant: TOKYO ELECTRON LIMITED, Tokyo (JP)

(72) Inventor: Mitsutoshi ASHIDA, Yamanashi (JP)

(21) Appl. No.: 19/315,206

(22) Filed: Aug. 29, 2025

(30) Foreign Application Priority Data
Sep. 9, 2024 (JP) 2024-155303

(51) Int. Cl. H01J 37/32; G01R 19/00

(52) U.S. Cl. CPC H01J 37/32917; G01R 19/0046; H01J 37/32862; H01J 2237/24564; H01J 2237/332

(57) ABSTRACT

Provided is a plasma measurement method for measuring a state of plasma using a probe device provided in a plasma processing apparatus and a measurement circuit including a signal generator that outputs a fixed AC current, the method comprising: measuring an initial plasma voltage by supplying the fixed AC current to the plasma via the probe device, in a state where the plasma is generated in an initial state of the plasma processing apparatus; measuring a measurement voltage in an operating state by supplying the fixed AC current to the plasma via the probe device, in a state where the plasma is generated in the plasma processing apparatus in the operating state; deriving a conductive deposition film voltage by subtracting the initial plasma voltage from the measurement voltage; and deriving a plasma state using a plasma voltage obtained by subtracting the conductive deposition film voltage from the measurement voltage.

### CROSS-REFERENCE TO RELATED APPLICATIONS

This application claims priority to Japanese Patent Application No. 2024-155303 filed on Sep. 9, 2024, the entire contents of which are incorporated herein by reference.

### TECHNICAL FIELD

The present disclosure relates to a plasma measurement method and a plasma measurement system.

### BACKGROUND

Japanese Laid-open Patent Publication No. 2019-46787 discloses a plasma probe device including an antenna part attached to an opening formed in a wall of a processing chamber or a placing table via a sealing member that seals a gap between a vacuum space and an atmospheric space, an electrode connected to the antenna part, and a dielectric support part made of a dielectric and configured to support the antenna part from the periphery thereof. The facing surfaces of the antenna part and the wall or the placing table are separated by a predetermined width, and the surface of the antenna part exposed from the opening is recessed from the surface of the wall or the placing table on the plasma generation space side where the opening is formed.

### SUMMARY

In one aspect, the present disclosure provides a plasma measurement method and a plasma measurement system for measuring the state of plasma.

In accordance with an aspect of the present disclosure, there is provided a plasma measurement method for measuring a state of plasma using a probe device provided in a plasma processing apparatus and a measurement circuit including a signal generator that outputs a fixed AC current, the method comprising: measuring an initial plasma voltage by supplying the fixed AC current output by the measurement circuit to the plasma via the probe device, in a state where the plasma is generated in an initial state of the plasma processing apparatus in which no conductive deposition film is deposited on the surface of the probe device; measuring a measurement voltage in an operating state by supplying the fixed AC current output by the measurement circuit to the plasma via the probe device, in a state where the plasma is generated in the plasma processing apparatus in the operating state in which the conductive deposition film is deposited on the surface of the probe device; deriving a conductive deposition film voltage by subtracting the initial plasma voltage from the measurement voltage; and deriving a plasma state using a plasma voltage obtained by subtracting the conductive deposition film voltage from the measurement voltage.

### BRIEF DESCRIPTION OF THE DRAWINGS

FIG. 1 is a schematic cross-sectional view showing an example of a plasma processing apparatus according to an embodiment.

FIG. 2 is a diagram showing an example of the II-II cross section of FIG. 1.

FIG. 3 is a diagram showing an example of a functional configuration of a measurement system and a controller according to an embodiment.

FIG. 4 is a flowchart showing an example of a control method for a plasma processing apparatus.

FIGS. 5A and 5B are graphs showing an example of a received signal received from a plasma side.

FIG. 6 is a diagram showing an example of a circuit model of a measurement system.

FIG. 7 is a diagram showing an example of a circuit model of a measurement system including a parasitic capacitance.

FIGS. 8A and 8B are diagrams showing an example of a vector diagram showing a current vector and a voltage vector.

FIG. 9 is a diagram showing an example of a circuit model of a measurement system for a second harmonic wave.

FIGS. 10A and 10B are diagrams showing an example of a vector diagram showing a current vector and a voltage vector.

FIGS. 11A and 11B are diagrams showing an example of a circuit model of deposits in a probe device.

FIG. 12 is a diagram showing another example of the circuit model of the measurement system.

FIG. 13 is a diagram showing an example of a flowchart explaining a method for deriving a plasma state.

### DETAILED DESCRIPTION

Hereinafter, embodiments of the present disclosure will be described in detail with reference to the accompanying drawings. Like reference numerals will be given to like parts throughout the drawings, and redundant description thereof may be omitted.

### (Plasma Processing Apparatus)

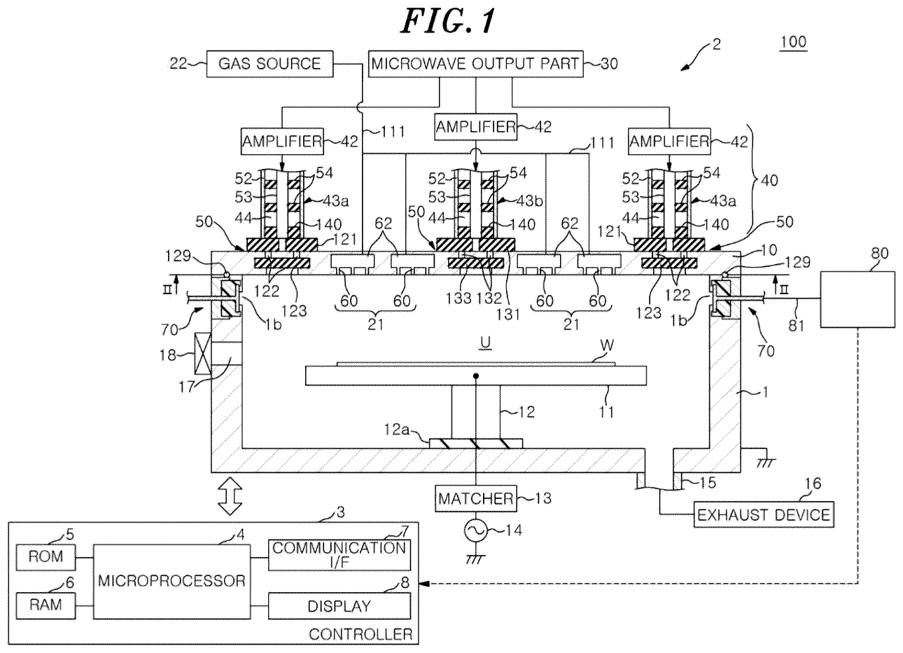

FIG. 1 shows an example of a cross-sectional view of a plasma processing apparatus 100 according to an embodiment of the present disclosure. The plasma processing apparatus 100 includes a processing chamber 1 that accommodates a substrate W that is an example of a semiconductor wafer. The plasma processing apparatus 100 is an example of a plasma processing apparatus that performs plasma processing on the substrate W by using surface wave plasma generated on the bottom surface of a ceiling wall 10 of the processing chamber 1 by microwaves. The plasma processing include film formation, etching, and ashing using plasma.

The plasma processing apparatus 100 includes the processing chamber 1, a microwave plasma source 2, and a controller 3. The processing chamber 1 is an airtight substantially cylindrical chamber made of a metal material such as aluminum or stainless steel. The processing chamber 1 is grounded.

The processing chamber 1 has the ceiling wall 10, and forms a space (plasma generation space U) for performing plasma processing on the substrate W therein. The ceiling wall 10 is a lid that is formed in a disc shape and closes the upper opening of the processing chamber 1. A support ring 129 is provided on the contact surface between the processing chamber 1 and the ceiling wall 10, thereby hermetically sealing the inside of the processing chamber 1. The ceiling wall 10 is made of a metal material such as aluminum or stainless steel.

The microwave plasma source 2 has a microwave output part 30, a microwave transmission part 40, and a microwave radiation mechanism 50. The microwave output part 30 distributes microwaves to a plurality of paths and outputs them. The microwaves are introduced into the processing chamber 1 through the microwave transmission part 40 and the microwave radiation mechanism 50. The gas supplied into the processing chamber 1 is excited by the electric field of the introduced microwaves, thereby generating surface wave plasma.

A placing table 11 for placing the substrate W is provided in the processing chamber 1. The placing table 11 is supported by a cylindrical support member 12 standing upright via an insulating member 12a at the center of the bottom portion of the processing chamber 1. The placing table 11 and the support member 12 may be made of a metal such as aluminum having an alumite-treated (anodically oxidized) surface, or an insulating member (ceramic or the like) having a high-frequency electrode therein. The placing table 11 may be provided with an electrostatic chuck for electrostatically attracting the substrate W, a temperature control mechanism, and a gas channel for supplying a heat transfer gas to the backside of the substrate W.

A high-frequency bias power supply 14 is connected to the placing table 11 via a matcher 13. When a high-frequency power is supplied from the high-frequency bias power supply 14 to the placing table 11, ions in the plasma are attracted toward the substrate W. The high-frequency bias power supply 14 may not be provided depending on the characteristics of the plasma processing.

An exhaust line 15 is connected to the bottom portion of the processing chamber 1, and an exhaust device 16 including a vacuum pump is connected to the exhaust line 15. When the exhaust device 16 operates, the processing chamber 1 is exhausted, and the processing chamber 1 is quickly depressurized to a predetermined vacuum level. A transfer port 17 for transferring the substrate W and a gate valve 18 for opening and closing the transfer port 17 are provided on the sidewall of the processing chamber 1.

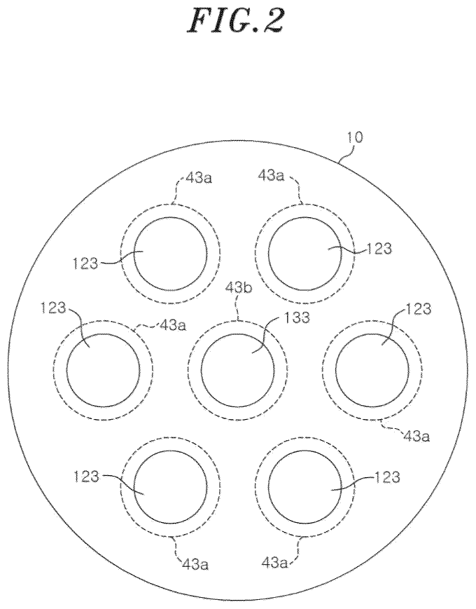

The microwave transmission part 40 transmits microwaves outputted from the microwave output part 30. FIG. 2 shows the cross section taken along line II-II in FIG. 1, and shows an example of the bottom surface of the ceiling wall of the plasma processing apparatus 100. Referring to FIG. 2, a central microwave introducing part 43b in the microwave transmission part 40 is located at the center of the ceiling wall 10, and six peripheral microwave introducing parts 43a are arranged at equal intervals in the circumferential direction around the ceiling wall 10. The central microwave introducing part 43b and the six peripheral microwave introducing parts 43a have the function of introducing microwaves outputted from corresponding amplifiers 42 shown in FIG. 1 into the microwave radiation mechanism 50, and the function of matching an impedance. Hereinafter, the peripheral microwave introducing parts 43a and the central microwave introducing part 43b are collectively referred to “microwave introducing part 43.”

As shown in FIGS. 1 and 2, six dielectric windows 123 on the outer peripheral side are located inside the ceiling wall 10 under the six peripheral microwave introducing parts 43a. The central dielectric window 133 is located inside the ceiling wall 10 under the central microwave introducing part 43b. The number of peripheral microwave introducing parts 43a and the number of dielectric windows 123 are not limited to six, and may be two or more. However, the number of peripheral microwave introducing parts 43a is preferably three or more, and may be three to six, for example.

The microwave radiation mechanism 50 shown in FIG. 1 includes wave retardation plates 121 and 131, slots 122 and 132, and dielectric windows 123 and 133. The wave retardation plates 121 and 131 are made of a disc-shaped dielectric that transmits microwaves, and are located on the upper surface of the ceiling wall 10. The wave retardation plates 121 and 131 are made of ceramic such as quartz or alumina (Al₂O₃), fluorine-based resin such as polytetrafluoroethylene, or polyimide-based resin, which have a relative dielectric constant greater than that of vacuum. Accordingly, the wave retardation plates 121 and 131 have a function of reducing a size of the antenna including the slots 122 and 132 by making the wavelength of the microwaves transmitted through the wave retardation members 121 and 131 shorter than the wavelength of the microwaves propagating in vacuum.

Under the wave retardation plates 121 and 131, the dielectric windows 123 and 133 are in contact with the back surface of the opening in the ceiling wall 10 via the slots 122 and 132 formed in the ceiling wall 10. The dielectric windows 123 and 133 are made of, for example, ceramic such as quartz or alumina (Al₂O₃), fluorine-based resin such as polytetrafluoroethylene, or polyimide-based resin. The dielectric windows 123 and 133 are located at positions recessed from the ceiling surface by the thickness of the opening formed in the ceiling wall 10, and are configured to supply microwaves to the plasma generation space U.

In the peripheral microwave introducing part 43a and the central microwave introducing part 43b, a cylindrical outer conductor 52 and a rod-shaped inner conductor 53 provided at the center of the cylindrical outer conductor 52 are coaxially arranged. A microwave power is supplied to the gap between the outer conductor 52 and the inner conductor 53, and the gap therebetween serves as a microwave transmission path 44 through which microwaves propagate toward the microwave radiation mechanism 50.

Each of the peripheral microwave introducing part 43a and the central microwave introducing part 43b is provided with a slug 54 and an impedance adjusting member 140 located at the tip end of the slug 54. The impedance adjusting member 140 has a function of matching an impedance of a load (plasma) in the processing chamber 1 with a characteristic impedance of a microwave power source in the microwave output part 30 by moving the slug 54. The impedance adjusting member 140 is made of a dielectric material, and is configured to adjust the impedance of the microwave transmission path 44 based on its relative dielectric constant.

The ceiling wall 10 is provided with a gas introducing part 21 having a shower structure. A gas supplied from a gas supply source 22 reaches the gas diffusion space 62 through a gas supply line 111, and is supplied into the processing chamber 1 in a shower pattern through the gas introducing part 21. The gas introducing part 21 is an example of a gas shower head for supplying a gas from a plurality of gas supply holes 60 formed in the ceiling wall 10. The gas may be a gas for plasma generation, such as Ar gas, a gas to be decomposed with high energy, such as O₂ gas or N₂ gas, a processing gas such as silane gas, or the like.

Individual components of the plasma processing apparatus 100 are controlled by the controller 3. The controller 3 includes a microprocessor 4, a read only memory (ROM) 5, and a random access memory (RAM) 6. A process sequence of the plasma processing apparatus 100 and a process recipe that is a control parameter are stored in the ROM 5 or the RAM 6. The microprocessor 4 controls the individual components of the plasma processing apparatus 100 based on the process sequence and the process recipe. Further, the controller 3 has a communication interface (I/F) 7, and can communicate with other devices. Further, the controller 3 has a display 8, and can display results at the time of performing predetermined control based on the process sequence and the process recipe.

In the case of performing plasma processing in the plasma processing apparatus 100 configured as described above, first, the substrate W is held on a transfer arm (not shown) and loaded into the processing chamber 1 from the open gate valve 18 through the loading/unloading port 17. When the substrate W is transferred to a position above the placing table 11, the substrate W is transferred from the transfer arm to a pusher pin and is placed on the placing table 11 by lowering the pusher pin. The gate valve 18 is closed after the substrate W is loaded.

The pressure in the processing chamber 1 is maintained at a predetermined vacuum level by the exhaust device 16. The processing gas is introduced into the processing chamber 1 from the gas introducing part 21 in a shower pattern. The microwaves emitted from the microwave radiation mechanism 50 via the microwave introducing part 43 propagate near the bottom surface that is the inner surface of the ceiling wall. The gas is excited by the electric field of the surface-wave microwave, and the substrate W is subjected to plasma processing by the surface wave plasma generated in the plasma generation space U under the ceiling wall in the processing chamber 1.

### (Probe Device)

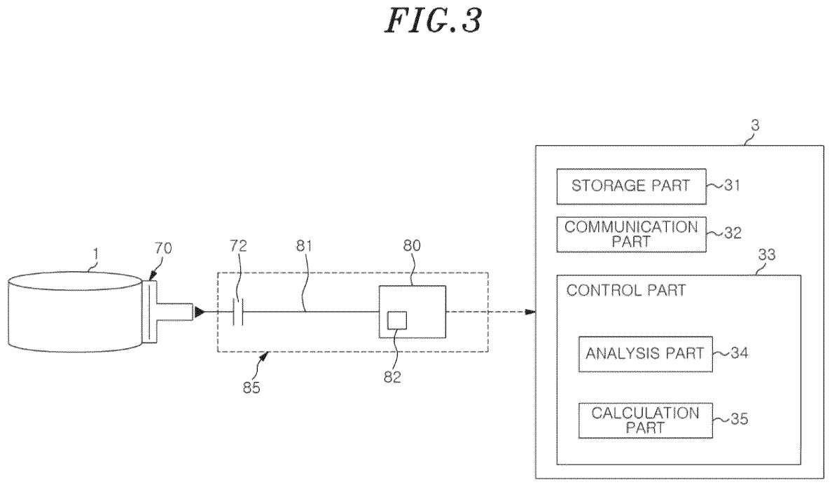

The probe device 70 will be described with reference to FIGS. 1 and 3. FIG. 3 is a diagram showing an example of a functional configuration of a measurement system and a controller according to one embodiment. As shown in FIG. 1, one or multiple openings 1b are formed in the sidewall of the processing chamber 1 in the circumferential direction, and one or multiple probe devices 70 are installed via a sealing member (not shown) for sealing the gap between a vacuum space and an atmospheric space.

A gap with a predetermined width is formed between the tip end surface of the probe device 70 and the back surface near the opening 1b formed in the wall of the processing chamber 1. The gap is designed to be wide enough to prevent the probe device 70 from being connected to the wall of the processing chamber 1 in a DC manner, and narrow enough to prevent inflow of plasma or a gas. However, the probe device 70 may be installed at the opening formed in the placing table via a sealing member.

As shown in FIG. 3, the measurement system for measuring a plasma state includes the probe device 70 and a measuring circuit 85. The measuring circuit 85 has a monitor device 80, a blocking capacitor 72, and a coaxial cable 81. The monitor device 80 is connected to the controller 3 to be able to communicate therewith.

The probe device 70 is connected to the monitor device 80 via the coaxial cable 81 outside the plasma processing apparatus 100. The monitor device 80 has a signal generator 82, and the signal generator 82 outputs an AC voltage signal of a predetermined frequency to the coaxial cable 81. The AC voltage signal is transmitted through the coaxial cable 81, and the AC voltage is applied to the probe device 70. The blocking capacitor 72 is connected to the coaxial cable 81, transmits the AC voltage signal to the probe device 70, and blocks the DC voltage signal. As a result, the monitor device 80 receives only the AC voltage signal from the plasma side.

The probe device 70 senses plasma generated in the plasma generation space U. The probe device 70 detects a current signal flowing to the plasma side from a signal transmitted to the plasma side, and transmits it to the monitor device 80. The current signal flowing to the plasma side is transmitted from the monitor device 80 to the controller 3, and is received by the communication part 32 of the controller 3. The current value of the received signal is stored in a storage part 31. An analysis part 34 of a control part 33 performs fast Fourier transform (FFT) analysis on the current value of the received signal. A calculation part 35 of the control part 33 calculates a plasma electron temperature Tₑ or a plasma electron density Nₑ based on the analysis result. Hence, the plasma state can be estimated accurately. As described above, the plasma measuring system for measuring the plasma state includes the probe device 70, the measuring circuit 85, and the controller 3 (the control part 33).

The storage part 31 is realized by the RAM 6 shown in FIG. 1. The communication part 32 is realized by a communication interface 7. The analysis part 34 and the calculation part 35 of the control part 33 are realized by the microprocessor 4.

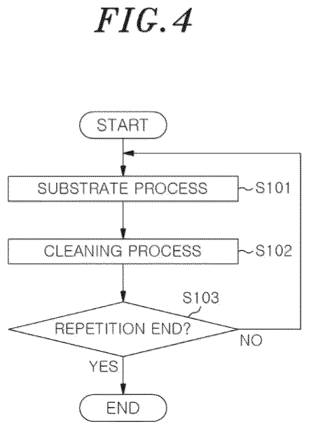

FIG. 4 is a flowchart showing an example of a method for controlling the plasma processing apparatus 100.

In step S101, the substrate processing is performed. Here, the controller 3 controls the gas supply source 22 to supply a processing gas (film forming gas, etching gas, or the like) from the gas supply holes 60 to the plasma generation space U, and controls the microwave output part 30 and the high frequency bias power supply 14 to generate plasma of the processing gas in the plasma generation space U, thereby performing desired processing (film formation, etching, or the like) on the substrate W. In this case, an AC voltage is applied from the signal generator 82 to the probe device 70, and the probe device 70 senses the plasma generated in the plasma generation space U. Then, the control part 33 calculates the plasma electron temperature Tₑ and the plasma electron density Nₑ to estimate the plasma state.

Here, if the substrate processing is a process for forming an insulating film on the substrate W, an insulator (e.g., SiN, SiO₂, or the like) is deposited on the surface (the tip end surface of the probe device 70, or the like) of the probe device 70 exposed to the plasma generation space U to form the insulating film. The substrate processing is not limited to the formation of the insulating film, and may be processing (e.g., etching) in which an insulator is formed as reaction by-products, and the reaction by-products (insulator) are deposited on the surface exposed to the plasma generation space U of the probe device 70 to form the insulating film.

In step S101, the substrate processing is repeated until cleaning start conditions such as a predetermined number of processed substrates and processing time are satisfied. When the predetermined cleaning start conditions are satisfied, the processing of the controller 3 proceeds to step S102.

In step S102, a cleaning process (dry cleaning process: a cleaning process using a cleaning gas without exposing the processing container to the atmosphere) is performed. Here, the controller 3 controls the gas supply source 22 to supply a cleaning gas (e.g., NF₃ or the like) containing fluorine (F) from the gas supply holes 60 to the plasma generation space U, and controls the microwave output part 30 and/or the high frequency bias power supply 14 to generate plasma of the cleaning gas in the plasma generation space U, thereby removing the insulating film deposited in the processing chamber 1. In addition, the insulating film deposited on the surface exposed to the plasma generation space U of the probe device 70 is also removed.

Here, in the cleaning process, conductive fluoride is adhered to and accumulated on the surface of the probe device 70 exposed to the plasma generation space U, thereby forming a conductive deposition film. The conductive fluoride is, for example, a metal fluoride (e.g., AlF) containing a metal (e.g., Al) derived from the inner wall of the processing chamber 1 and the dielectric window 123, 133 made of alumina (Al₂O₃), and fluorine (F) derived from the cleaning gas. The deposited metal fluoride has lattice defects, and thus is conductive.

In step S103, it is determined whether or not to end the repetition. If the repetition is not ended (S103, NO), the process of the controller 3 returns to step S101, and the substrate processing and the cleaning process are repeated. If the repetition is ended (S103, YES), the process of the controller 3 is ended. In addition, a cleaning process (wet cleaning: a cleaning process in which the processing chamber is exposed to the atmosphere) and the like are performed.

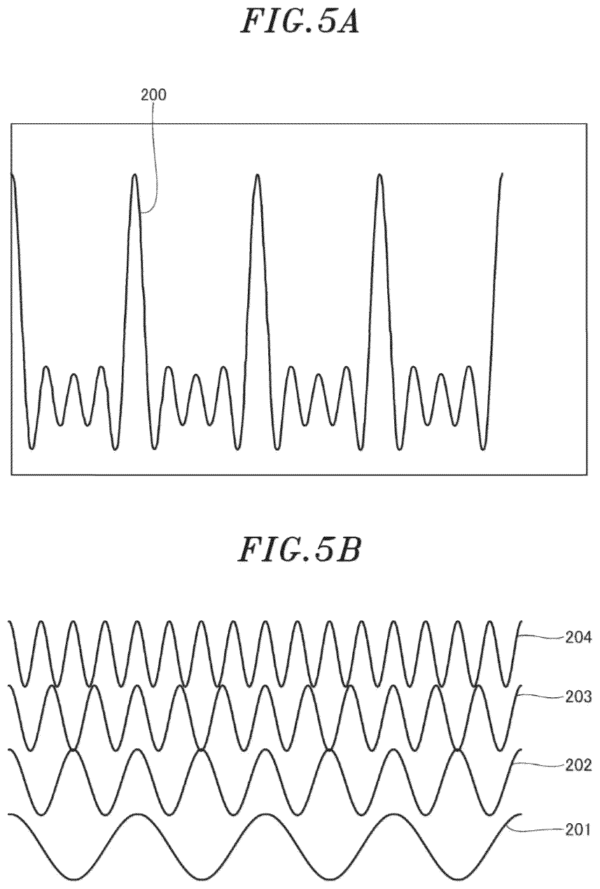

Here, an example of the measurement of the plasma state will be described. FIG. 5 is a graph showing an example of a received signal received from the plasma side.

FIG. 5A is a graph showing an example of raw data of a received signal detected by the probe device 70 and received by the monitor device 80. The horizontal axis represents time, and the vertical axis represents the strength (current value) of the received signal. As shown in FIG. 5A, the monitor device 80 receives a received signal 200 from the probe device 70.

FIG. 5B is a graph showing an example of the analysis result of the analysis part 34 of the control part 33. The analysis part 34 performs fast Fourier transform (FFT) analysis on the current value of the received signal 200. Accordingly, the received signal 200 is decomposed into frequency components such as a fundamental wave component (fundamental harmonic wave component) 201, a second harmonic wave component 202, a third harmonic wave component 203, and a fourth harmonic wave component 204. Further, the calculation part 35 of the control part 33 calculates the plasma electron temperature Tₑ and the plasma ion density nᵢ based on the FFT analysis result. Accordingly, the plasma state is measured. Further, the plasma electron temperature Tₑ and the plasma ion density nᵢ are calculated based on the fundamental wave component 201 and the second harmonic component 202, as will be described later.

### (Method for Measuring Plasma State)

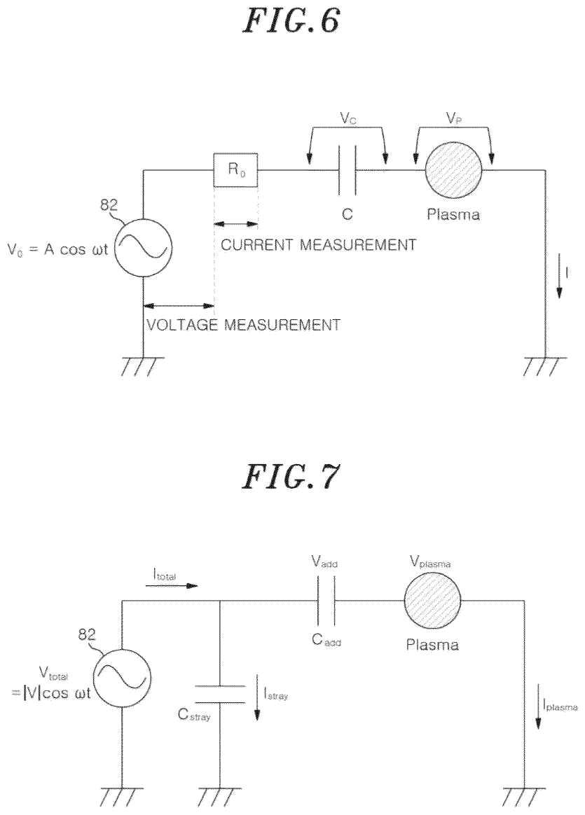

Next, the method for measuring the plasma electron temperature Tₑ and the plasma ion density nᵢ will be described with reference to FIG. 6. FIG. 6 shows an example of a circuit model of the measurement system.

As shown in FIG. 6, the insulating film is deposited on the probe device 70, and thus has a capacitance component C. The voltage of the insulating film (capacitance component C) is set as V_{c}, and the voltage of the plasma is set as Vₚ. Further, the monitor device 80 has a voltage measuring part (not shown) that measures a voltage (output terminal AC voltage) supplied to the plasma at the output terminal of the signal generator 82, and a current measuring partn (not shown) that measures a current. R₀ is a resistor for measuring the current. The resistance value thereof is known, and is sufficiently small compared to the resistance value of the plasma. The current supplied to the plasma is measured by measuring voltages on both sides of R₀.

Here, the plasma is considered to be a pure resistance (phase difference) 0°, and the insulating film has the capacitance component C with a phase difference of 90°, so that it is possible to separately estimate the thickness (the capacitance component C) of the insulating film and the plasma state (the plasma electron temperature Tₑ and the plasma ion density nᵢ).

The current I flowing through the circuit model can be expressed by the following equation using the plasma voltage Vₚ. Iᵢₛ is an ion saturation current, Iₑₛ is an electron saturation current, V_{f} is a floating voltage, Pp is a plasma voltage, Tₑ is a plasma electron temperature (eV), nₑ is a plasma electron density, nᵢ is a plasma ion density, S is a probe area, Mᵢ is an ion mass (kg), and me is an electron mass (kg).

$$I = f ( {V}_{p} ) \qquad [ Eq . ( 1 ) ]$$

$$f ( V ) = {I}_{e s} exp ( \frac{{V}_{f} - {ϕ}_{p}}{{T}_{e}} ) exp ( \frac{V}{{T}_{e}} ) - {I}_{i s}$$

$${I}_{i s} = exp ( - \frac{1}{2} ) e {n}_{i} S \sqrt{\frac{e {T}_{e}}{{M}_{i}}}$$

$${I}_{e s} = \frac{1}{4} e {n}_{e} S \sqrt{\frac{8 e {T}_{e}}{π {m}_{e}}}$$

Next, it is assumed that Vₚ=V₀=Acosωt. A indicates an amplitude of an AC voltage outputted by the signal generator 82. The equation for the current I flowing through the circuit model described above is transformed using the first type modified Bessel function Iₖ(x). Accordingly, the equation for the current I is decomposed into frequency components.

$$\begin{matrix}I = {l}_{e s} exp ( \frac{{V}_{f} - {ϕ}_{p}}{{T}_{e}} ) exp ( \frac{{V}_{0} cos ω t}{{T}_{e}} ) - {I}_{i s} \\ = {I}_{e s} exp ( \frac{{V}_{f} - {ϕ}_{p}}{{T}_{e}} ) {I}_{0} ( \frac{{V}_{0}}{{T}_{e}} ) - {I}_{i s} + \\ 2 {I}_{e s} exp ( \frac{{V}_{f} - {ϕ}_{p}}{{T}_{e}} ) {\sum }_{k = 1}^{∞} {I}_{k} ( \frac{{V}_{0}}{{T}_{e}} ) cos ( k ω t )\end{matrix} \qquad [ Eq . ( 2 ) ]$$

Here, the information on the plasma electron density nₑ is contained only in the coefficients Iₑₛ of each frequency component. Therefore, the plasma electron density nₑ is deleted from the equation by dividing the fundamental wave current i_{1ω} by the second harmonic wave current i_{2ω}.

$$\frac{{i}_{1 ω}}{{i}_{2 ω}} = \frac{{I}_{1} ( \frac{{V}_{0}}{{T}_{e}} )}{{I}_{2} ( \frac{{V}_{0}}{{T}_{e}} )} \qquad [ Eq . ( 3 ) ]$$

The plasma electron temperature Tₑ is calculated from the above equation.

Further, the plasma ion density nᵢ can be expressed by the following equation. The plasma ion density nᵢ can be calculated using the following equation, the calculated plasma electron temperature Tₑ, and the fundamental wave current i_{1ω}.

$${η}_{i} = \frac{{i}_{1 ω}}{2 exp ( - \frac{1}{2} ) eS \sqrt{\frac{{eT}_{e}}{{M}_{i}}}} \frac{{I}_{0} ( \frac{{V}_{0}}{{T}_{e}} )}{{I}_{1} ( \frac{{V}_{0}}{{T}_{e}} )} \qquad [ Eq . ( 4 ) ]$$

### (Method for Measuring Plasma State in Consideration of Parasitic Capacitance)

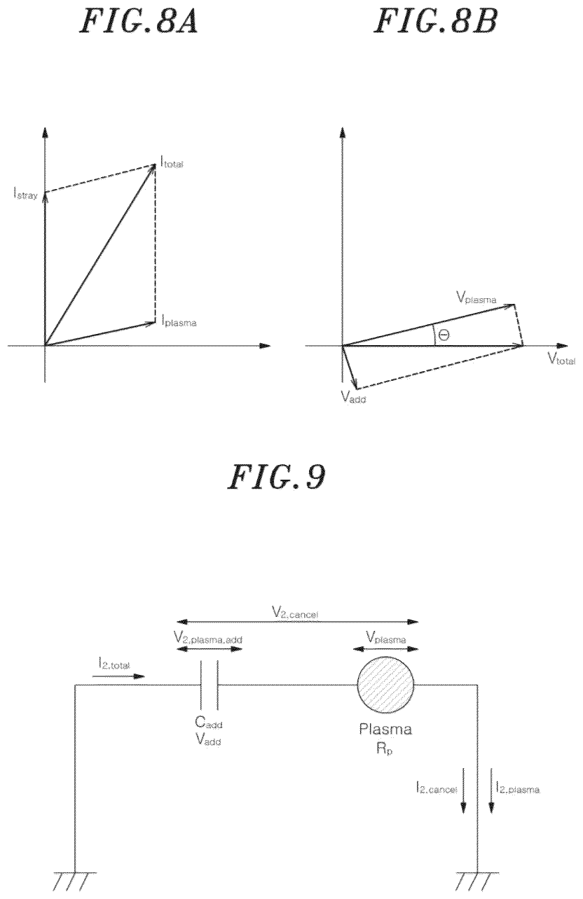

FIG. 7 is an example of a circuit model of a measurement system including parasitic capacitance (floating capacitance). FIG. 8 is an example of a vector diagram showing a current vector and a voltage vector.

A voltage Vₜₒₜₐₗ is a voltage measured by the voltage measuring part (not shown) of the monitor device 80. A current Iₜₒₜₐₗ is a current measured by the current measuring part (not shown) of the monitor device 80. A voltage Vₚₗₐₛₘₐ is a plasma voltage. A current Iₚₗₐₛₘₐ is a plasma current. The voltage Vₚₗₐₛₘₐ and the current Iₚₗₐₛₘₐ are used at the time of measuring the plasma state (the plasma electron temperature Tₑ and the plasma ion density nᵢ).

Here, the circuit includes a series capacitance C_{add} in series with the signal generator 82, and a parasitic capacitance C_{stray} in parallel with the signal generator 82. Thus, a difference occurs between the voltage Vₚₗₐₛₘₐ and the current Iₚₗₐₛₘₐ of the plasma that are used at the time of measuring the plasma state (the plasma electron temperature Tₑ and the plasma ion density nᵢ) and the voltage Vₜₒₜₐₗ and the current Iₜₒₜₐₗ measured by the monitor device 80.

In the parasitic capacitance C_{stray} in parallel with the signal generator 82, a component that escapes to the ground voltage GND from the capacitance existing on the circuit such as the coaxial cable 81 or the like is dominant. Hence, it is generated regardless of the presence/absence of plasma. Therefore, in the extinguished state of plasma, the current I_{stray} is measured from the current Iₜₒₜₐₗ measured by the current measuring part (not shown) of the monitor device 80.

In the ignited state of plasma, as shown in FIG. 8A, the current Iₜₒₜₐₗ is expressed as the vector sum of the current Iₚₗₐₛₘₐ and the current I_{stray}. Therefore, the current vector of the plasma current Iₚₗₐₛₘₐ can be calculated by calculating the current vector difference obtained by subtracting the current vector of the current I_{stray} measured in advance from the current vector of the current Iₜₒₜₐₗ measured by the current measuring part (not shown) of the monitor device 80.

A series capacitance C_{add} in series with the signal generator 82 represents the series capacitance component such as the capacitor for insulation in the probe device 70 and the insulating film (SiN or the like) formed by deposits. When the current Iₚₗₐₛₘₐ flows, a voltage V_{add} that is 90 degrees behind the current Iₚₗₐₛₘₐ is generated. The effect of the parallel parasitic capacitance C_{stray} on the plasma is assumed to be sufficiently small. Further, the voltage Vₚₗₐₛₘₐ and the current Iₚₗₐₛₘₐ of the plasma are assumed to be in phase.

As shown in FIG. 8B, the voltage Vₜₒₜₐₗ is expressed as the vector sum of the voltage Vₚₗₐₛₘₐ and the voltage V_{add}. Therefore, the voltage Vₚₗₐₛₘₐ can be calculated by using the phase difference θ between the voltage Vₚₗₐₛₘₐ and the voltage Vₜₒₜₐₗ as follows: voltage Vₚₗₐₛₘₐ=Vₜₒₜₐₗ×cose.

In this manner, the calculation part 35 can accurately calculate the voltage Vₚₗₐₛₘₐ and the current Iₚₗₐₛₘₐ of the plasma from the measurement voltage Vₜₒₜₐₗ and current Iₜₒₜₐₗ by correcting (calibrating) the difference due to the series capacitance C_{add} and the parasitic capacitance C_{stray}. Accordingly, the plasma state (the plasma electron temperature Tₑ and the plasma ion density nᵢ) can be measured with high accuracy.

### (Second Harmonic Wave Current)

A high voltage is generated at the capacitor inserted in the circuit model of the measurement system by a nonlinear current generated by the plasma. As a result, a high current is superimposed on the plasma (see FIG. 5). Similarly to the case of the fundamental wave (fundamental harmonic wave) described with reference to FIGS. 7 and 8, the vector of the total high current and the vector of the generated high current are orthogonal and, thus, this component can be corrected (calibrated) by measuring the phase between the fundamental wave current and the second harmonic wave current.

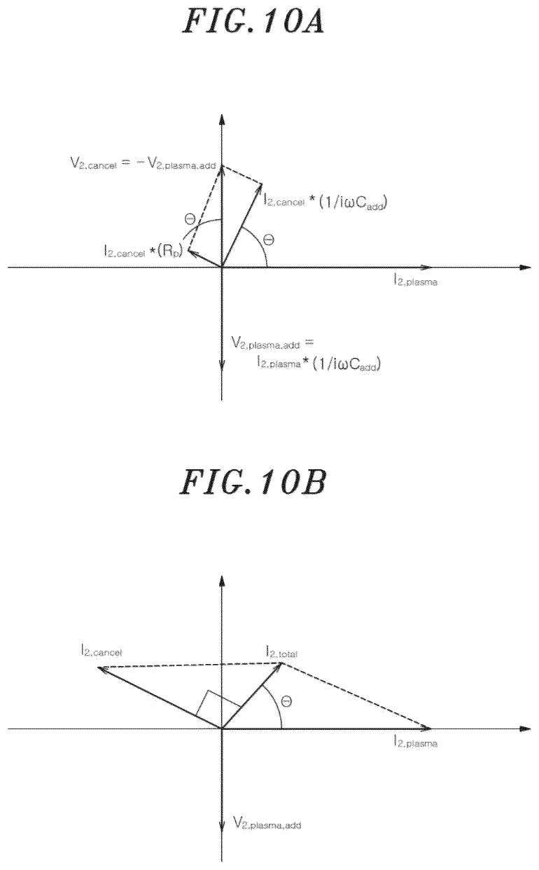

Hereinafter, the second harmonic wave current will be described. FIG. 9 is an example of a circuit model of a measurement system for a second harmonic wave. FIG. 10 is an example of a vector diagram showing a current vector and a voltage vector.

The voltage Vₚₗₐₛₘₐ is the voltage obtained by dividing the voltage Vₜₒₜₐₗ (see FIG. 7) into the voltage V_{add} and the voltage Vₚₗₐₛₘₐ. However, the voltage Vₚₗₐₛₘₐ is only the fundamental wave voltage. In other words, the signal generator 82 outputs a fundamental wave voltage. Therefore, the circuit model of the measurement system for the second harmonic wave shown in FIG. 9 does not have the signal generator 82.

A voltage V_{2,plasma} is a second harmonic wave voltage applied to the plasma that is required to cause a current I_{2,cancel} to be described later to flow through the plasma.

A current I_{2,plasma} is a second harmonic wave current that is derived by applying the voltage Vₚₗₐₛₘₐ to the plasma. This is generated because the current response in the plasma is nonlinear.

A voltage V_{2,plasma}, add is a second harmonic wave current that is generated by the current I_{2,plasma} flowing through the series capacitance C_{add}. The voltage V_{2,plasma}, add can be expressed by the following equation.

$${V}_{2 , plasma , add} = {I}_{2 , plasma} \times ( 1 / i ω {C}_{add} )$$

A voltage V_{2,cancel} is a voltage generated by the second harmonic wave current I_{2,cancel} that flows to cancel the voltage V_{2,plasma}, add required by Kirchhoff's law. The voltage V_{2,cancel} can be expressed by the following equation.

$${V}_{2 , cancel} = - {V}_{2 , plasma , add}$$

The current I_{2,cancel} is a second harmonic wave current that flows to generate the voltage V_{2,cancel}. The current I_{2,cancel} can be expressed by the following equation. The pure resistance of the plasma is Rₚ. The current I_{2,cancel} also flows through the series capacitance C_{add}, so that a voltage is also generated thereat.

$${I}_{2 , cancel} = {V}_{2 , cancel} / ( 1 / i ω {C}_{add} + {R}_{p} ) = - {I}_{2 , plasma} \times ( 1 / i ω {C}_{add} ) / ( 1 / i ω {C}_{add} + {R}_{p} )$$

A current I_{2,total} is the amount of the second harmonic wave current flowing through the entire circuit, and is the sum of the current I_{2,plasma} and the current I_{2,cancel}. In other words, current I_{2,total} can be expressed by the following equation.

$${I}_{2 , total} = {I}_{2 , plasma} + {I}_{2 , cancel} = {I}_{2 , plasma} \times ( {R}_{p} ) / ( 1 / i ω {C}_{a d d} + {R}_{p} )$$

Here, the current I_{2,total} corresponds to the real part when the current I_{2,plasma} is expressed in complex space, and thus can be expressed by the following equation.

$${I}_{2 , plasma} = {I}_{2 , total} / cos θ$$

Here, the current I_{2,plasma} is the second harmonic wave current generated by the fundamental wave voltage Vₚₗₐₛₘₐ calculated by the above equation. Therefore, the second harmonic wave current I_{2,plasma} has the same phase as the fundamental wave current Iₚₗₐₛₘₐ. Hence, the phase θ represents the phase difference between the fundamental wave current and the second harmonic wave current.

Further, the following equations are satisfied.

$${I}_{2 , total} = {I}_{2 , plasma} + {I}_{2 , cancel}$$

$${I}_{2 , total} ( 1 / i ω {C}_{add} + {R}_{p} ) = ( {I}_{2 , plasma} + {I}_{2 , cancel} ) ( 1 / i ω {C}_{add} + {R}_{p} )$$

$${I}_{2 , total} ( 1 / i ω {C}_{a d d} + {R}_{p} ) = {I}_{2 , plasma} \times {R}_{p}$$

The current I_{2,total} indicates that the current I_{2,cancel} and the current I_{2,plasma} cancel each other out. Rₚ/(1/iωC_{add}+Rₚ) indicates the cosine of the phase angle θ of the current I_{2,total} with respect to the current I_{2,plasma}, and the current I_{2,plasma} is in phase with the plasma voltage Vₚₗₐₛₘₐ and the fundamental wave current I.

As described above, by accurately determining the fundamental wave current and the second harmonic wave current, the plasma state (the plasma electron temperature Tₑ and the plasma ion density nᵢ) can be accurately determined.

### (Control for Conductive Deposits)

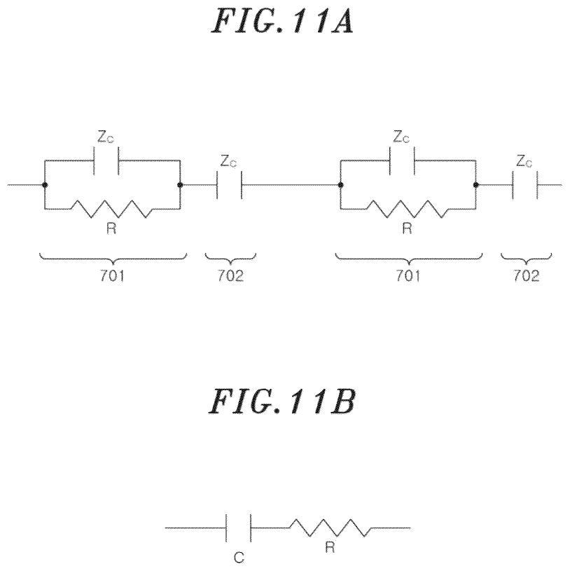

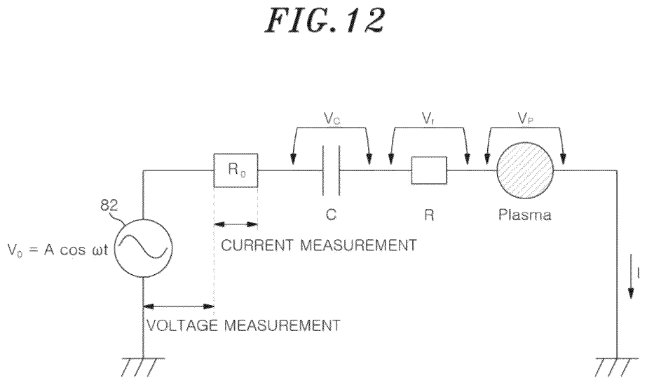

FIG. 11 is a diagram showing an example of a circuit model of deposits in the probe device 70. FIG. 12 shows another example of the circuit model of the measurement system.

Here, by performing substrate processing and cleaning processing (dry cleaning) as shown in FIG. 4, a conductive deposition film (conductive fluoride, metal fluoride, AlF), an insulating film (e.g., SiN film), and the like are deposited on the surface of the probe device 70. Further, the impedance component originating from the conductive deposition film has a resistance component and a capacitance component connected in parallel. The impedance component originating from the insulating film has a capacitance component.

In other words, on the surface of the probe device 70, the conductive deposition film deposited during the cleaning process and the insulating film that was not completely removed during the cleaning process are alternately deposited, and the insulating film deposited after the cleaning process is deposited. Therefore, as shown in FIG. 11A, in the circuit model, impedance components 701 originating from the conductive deposition film and impedance components 702 originating from the insulating film are alternately arranged in series. In addition, the circuit model shown in FIG. 11A can be converted to an equivalent model shown in FIG. 11B in which the capacitance component C and the resistance component R are arranged in series.

Therefore, as shown in FIG. 12, in the circuit model of plasma measurement using the probe device 70, the capacitance component C and the resistance component R are added in series with the plasma by the deposition of the insulating film and the conductive deposition film on the surface of the probe device 70. The resistance component R changes depending on the deposition state of the conductive deposition film. Further, the capacitance component C changes depending on the deposition state of the insulating film and the conductive deposition film.

Here, the voltage of the capacitance component C is set as Vc, the voltage of the resistance component R is set as Vr, and the voltage of the plasma is set as Vp. Further, the monitor device 80 has a voltage measuring part (not shown) that measures the voltage supplied to the plasma from the signal generator 82, and a current measuring part (not shown) that measures the current. Here, R₀ denotes a resistor for measuring the current, and the resistance value thereof is known and is sufficiently small compared to the resistance value of the plasma.

Here, the plasma is considered as a pure resistance with a phase difference of 0° and the insulating film has the capacitance component C with a phase difference of 90°, so that it is possible to estimate the thickness of the insulating film (capacitance component C) and the state of the plasma (the plasma electron temperature Tₑ and the plasma ion density nᵢ) separately. The resistance component R is located in series with the plasma, so that it is difficult to separate the voltage Vr of the resistance component R from the plasma voltage Vₚ.

Therefore, the deposition of the conductive deposition film on the surface of the probe device 70 may result in a decrease in the measurement accuracy of the plasma voltage Vₚ, and a decrease in the estimation accuracy of the state of the plasma (the plasma electron temperature Tₑ and the plasma ion density nᵢ). For example, due to the deposition of the conductive deposition film on the surface of the probe device 70 by repeating the substrate processing and the cleaning processing, the estimated plasma electron temperature Tₑ may be higher than the actual plasma electron temperature Tₑ. Further, as the conductive deposition film on the surface of the probe device 70 increases, the estimated plasma electron temperature Tₑ increases, and the difference between the estimated plasma electron temperature Tₑ the actual plasma electron temperature Tₑ increases, which may result in deterioration of the accuracy of estimating the plasma electron temperature Tₑ.

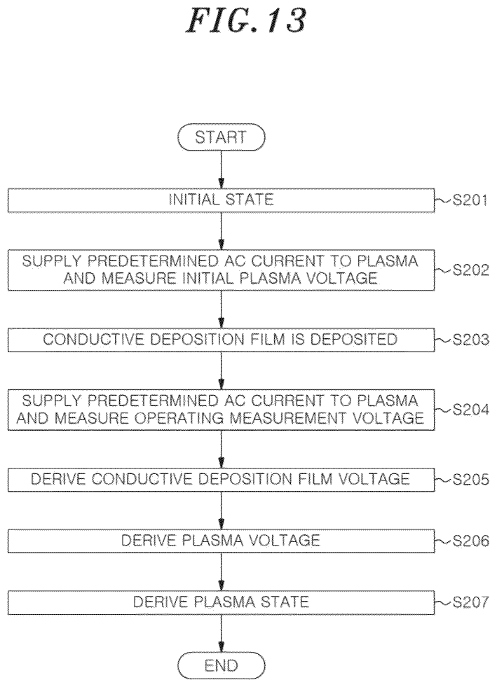

FIG. 13 is an example of a flowchart for explaining a method for deriving a plasma state. Here, even if a conductive deposition film is deposited on the surface of the probe device 70, the plasma voltage Vₚ is derived with high accuracy. Specifically, the current flowing through the plasma is maintained at a constant level to control the plasma voltage to be constant.

In step S201, the surface of the probe device 70 is set to an initial state. Here, the initial state is a state in which no conductive deposition film is deposited on the surface of the probe device 70. Specifically, the initial state may be a state in which a new probe device 70 is installed. Further, the initial state may be a state in which the conductive deposition film is removed by performing wet cleaning on the surface of the probe device 70.

In step S202, initial plasma is generated, and an initial plasma voltage Vₚᵢₙᵢₜᵢₐₗ is measured. Here, the controller 3 controls the microwave output part 30 to supply predetermined microwaves to the microwave radiation mechanism 50, thereby generating plasma in the processing chamber 1. Further, the controller 3 controls the signal generator 82 to supply a predetermined AC current I to the plasma. Further, the controller 3 measures the initial plasma voltage Vₚᵢₙᵢₜᵢₐₗ via the probe device 70 and the monitor device 80. In other words, the signal generator 82 performs control such that the fundamental wave (fundamental harmonic wave) of the current measured by the current measuring part becomes the predetermined AC current I. In this case, the voltage measured by the voltage measuring part is set as the initial plasma voltage Vₚᵢₙᵢₜᵢₐₗ.

In the initial state, no conductive deposition film is deposited on the surface of the probe device 70, and the circuit model shown in FIG. 6 is obtained. Therefore, the voltage measured by the voltage measuring part is set as the initial plasma voltage Vₚᵢₙᵢₜᵢₐₗ. Further, it is preferable to detect the initial plasma voltage Vₚᵢₙᵢₜᵢₐₗ by eliminating the influence of the parasitic capacitance, as described above with reference to FIGS. 7 to 10.

In step S203, the conductive deposition film is deposited on the surface of the probe device 70. Here, as shown in FIG. 4, the substrate processing (step S101) and the cleaning processing (step S102) are repeated. As a result, a conductive deposition film, an insulating film, and the like are deposited on the surface of the probe device 70.

In step S204, operating plasma is generated, and an operating measurement voltage V_{poperating} is measured. Here, the controller 3 controls the microwave output part 30 to supply predetermined microwaves to the microwave radiation mechanism 50, thereby generating plasma in the processing chamber 1. Further, the controller 3 controls the signal generator 82 to supply a predetermined AC current I to the plasma. Further, the controller 3 measures the operating measurement voltage V_{poperating} via the probe device 70 and the monitor device 80. In other words, the signal generator 82 controls the fundamental wave (fundamental harmonic wave) of the current measured by the current measuring part to be the predetermined AC current I. In this case, the voltage detected by the voltage measuring part is set as the operating measurement voltage V_{poperating}.

The predetermined AC current I supplied to the plasma in step S204 is the same value as the predetermined AC current I supplied to the plasma in step S202. In other words, by making the current flowing through the plasma constant, the fundamental wave voltage Vₚ applied to the plasma is also constant as long as the plasma state does not change, and the second harmonic wave current I_{2,plasma} that is a distortion component is also constant.

The operating state is a state after the initial state, in which the cleaning process (step S102) has been performed at least once and the conductive deposition film has been deposited on the surface of the probe device 70. In the operating state, the conductive deposition film is deposited on the surface of the probe device 70, and the circuit model shown in FIG. 12 is obtained. Therefore, the measurement voltage V_{poperating} measured by the voltage measuring part is the sum of the plasma voltage Vₚ and the conductive deposition film voltage Vᵣ (V_{poperating}=Vₚ+Vᵣ).

In step S205, the conductive deposition film voltage Vᵣ is derived. Here, the conductive deposition film voltage Vᵣ is derived by subtracting the initial plasma voltage Vₚᵢₙᵢₜᵢₐₗ measured in step S202 from the operating measurement voltage V_{poperating} measured in step S204 (Vᵣ=V_{poperating}−Vₚᵢₙᵢₜᵢₐₗ).

In step S206, the actual plasma voltage Vₚ is derived. Here, the actual plasma voltage Vₚ in the operating state is derived by subtracting the conductive deposition film voltage Vᵣ from the operating measurement voltage V_{poperating} (Vₚ=V_{poperating}−Vᵣ).

In step S207, the plasma state (the plasma electron temperature Tₑ and the plasma ion density nᵢ) is derived. Here, the plasma state (the plasma electron temperature Tₑ and the plasma ion density nᵢ) is derived based on the plasma voltage Vₚ derived in step S206, the predetermined AC current I, or the like.

Accordingly, even if the conductive deposition film is deposited on the surface of the probe device 70, the plasma voltage Vₚ can be appropriately derived, and the plasma state (the plasma electron temperature Tₑ and the plasma ion density nᵢ) can be derived.

Further, in the substrate processing performed after the initial plasma voltage Vₚᵢₙᵢₜᵢₐₗ is measured in the initial state and before the first cleaning process (step S102) is performed, the plasma voltage Vₚ can be derived using the circuit model shown in FIG. 6, on the assumption that the conductive deposition film is not deposited on the surface of the probe device 70. Further, the plasma state (the plasma electron temperature Tₑ and the plasma ion density nᵢ) can be derived based on the derived plasma voltage Vₚ or the like.

After the first cleaning process (steps S102 and S203) is performed, the conductive deposition film voltage Vᵣ is derived by the processes of steps S204 and S205. Further, the thickness of the conductive deposition film may be estimated based on the conductive deposition film voltage Vᵣ.

In the substrate processing performed before the second cleaning process (step S102) is performed, the plasma voltage Vₚ can be derived using the circuit model shown in FIG. 12 and the derived conductive deposition film voltage Vᵣ (step S206). Further, the plasma state (the plasma electron temperature Tₑ and the plasma ion density nᵢ) can be derived based on the derived plasma voltage Vₚ or the like (step S207).

In the same manner, whenever the cleaning process (steps S102 and S203) is performed, the conductive deposition film voltage Vᵣ is derived (steps S204 and S205), and in the substrate processing performed until the next cleaning process (step S102) is performed, the plasma voltage Vₚ can be derived (step S206) using the circuit model shown in FIG. 12 and the derived conductive deposition film voltage Vᵣ. Further, the plasma state (the plasma electron temperature Tₑ and the plasma ion density nᵢ) can be derived based on the derived plasma voltage Vₚ or the like (step S207).

Further, in the initial state of step S202 and the operating state of step S204, the second harmonic wave current I_{2,plasma} may be obtained by the processing shown in FIGS. 9 and 10.

Hereinafter, the second harmonic wave current I_{2,plasma} obtained in the initial state will be referred to as “second harmonic wave current I_{2,plasma}, initial” and the second harmonic wave current I_{2,plasma} obtained in the operating state will be referred to as “second harmonic wave current I_{2,plasma,operating}.”

Here, the second harmonic wave current I_{2,plasma,operating} obtained in the operating state (state in which the conductive deposition film is deposited) has the following relationship.

Second harmonic wave current I_{2,plasma,operating} obtained in the operating state=plasma voltage V_{2,plasma}/(plasma voltage V_{2,plasma}+conductive deposition film voltage Vᵣ)×actual second harmonic wave current I_{2,plasma}

Here, the actual second harmonic wave current I_{2,plasma} in the operating state is equal to the second harmonic wave current I_{2,plasma,initial} in the initial state, so that V_{2,plasma}/(V_{2,plasma}+Vᵣ) can be derived by dividing the second harmonic wave current I_{2,plasma,operating} obtained in the operating state by the second harmonic wave current I_{2,plasma,initial} obtained in the initial state.

By monitoring the conductive deposition film voltage Vᵣ derived in step S205 and/or V_{2,plasma}/(V_{2,plasma}+Vᵣ) obtained from the second harmonic wave current I_{2,plasma} in the initial state and the second harmonic wave current I_{2,plasma} in the operating state, the state (film thickness) of the conductive deposition film deposited on the surface of the probe device 70 can be monitored. If these values are not within a predetermined range, it may be determined that wet cleaning needs to be performed on the surface of the probe device 70.

Further, whether the plasma processing apparatus 100 is normal or abnormal may be determined based on the variation in the conductive deposition film voltage Vᵣ. If the conductive deposition film voltage Vᵣ changes abruptly compared to the previous value during substrate processing, it is assumed that the plasma voltage Vₚ also changes abruptly, and the plasma processing apparatus 100 may be determined to be abnormal. Further, if the conductive deposition film voltage Vᵣ changes abruptly compared to the previous value during cleaning processing, it is assumed that the deposition amount of the conductive deposition film changes abnormally, and the plasma processing apparatus 100 may be determined to be abnormal. Further, if the second harmonic wave current I_{2,plasma} or the conductive deposition film voltage Vᵣ deviates from the reference value by more than ±10%, for example, the plasma processing apparatus 100 is determined to be abnormal, and next substrate processing may be stopped. When the plasma processing apparatus 100 is determined to be abnormal, the processing chamber 1 may be opened and subjected to maintenance or the like.

While the plasma processing apparatus 100 has been described, the present disclosure is not limited to the above embodiment, and various modifications and improvements can be made within the scope of the gist of the present disclosure described in the claims.

1. A plasma measurement method for measuring a state of plasma using a probe device provided in a plasma processing apparatus and a measurement circuit including a signal generator that outputs a fixed AC current, the method comprising:
measuring an initial plasma voltage using the measurement circuit by supplying the fixed AC current to the plasma via the probe device, in a state where the plasma is generated in an initial state of the plasma processing apparatus in which no conductive deposition film is deposited on the surface of the probe device;
measuring a measurement voltage in an operating state using the measurement circuit by supplying the fixed AC current to the plasma via the probe device, in a state where the plasma is generated in the plasma processing apparatus in the operating state in which the conductive deposition film is deposited on the surface of the probe device;
deriving a conductive deposition film voltage by subtracting the initial plasma voltage from the measurement voltage; and
deriving a plasma state using a plasma voltage obtained by subtracting the conductive deposition film voltage from the measurement voltage.

2. The plasma measurement method of claim 1, further comprising:
dry-cleaning the inside of a processing chamber of the plasma processing apparatus using a fluorine-containing gas after the initial state and before the operating state.

3. The plasma measurement method of claim 2, wherein said measuring the measurement voltage and said deriving the conductive deposition film voltage are performed after said dry-cleaning is ended.

4. The plasma measurement method of claim 1, wherein a thickness of the conductive deposition film is estimated based on a ratio of a second harmonic wave current in the initial state to a second harmonic wave current in the operating state.

5. The plasma measurement method of claim 1, wherein an abnormality of the plasma processing apparatus is determined based on the conductive deposition film voltage.

6. A plasma measurement system for measuring a state of plasma, comprising:
a probe device provided in a plasma processing apparatus;
a measurement circuit including a signal generator configured to output a fixed AC current; and
a controller,
wherein the controller is configured to execute:
measuring an initial plasma voltage using the measurement circuit by supplying the fixed AC current to the plasma via the probe device, in a state where the plasma is generated in an initial state of the plasma processing apparatus in which no conductive deposition film is deposited on the surface of the probe device;
measuring a measurement voltage in an operating state using the measurement circuit by supplying the fixed AC current to the plasma via the probe device, in a state where the plasma is generated in the plasma processing apparatus in the operating state in which the conductive deposition film is deposited on the surface of the probe device;
deriving a conductive deposition film voltage by subtracting the initial plasma voltage from the measurement voltage; and
deriving a plasma state using a plasma voltage obtained by subtracting the conductive deposition film voltage from the measurement voltage.
